(19) United States
(12) Patent Application Publication
(10) Pub. No.: US 2008/0166657 A1
(43) Pub. Date: Jul. 10, 2008

(54) Resist composition for bulkhead formation, bulkhead of EL display device and EL display device

(76) Inventors: Yasuaki Sugimoto, Kawasaki-shi (JP); Kiyoshi Uchikawa, Kawasaki-shi (JP)

Correspondence Address: WENDEROTH, LIND & PONACK, L.L.P., 2033 K STREET N. W., SUITE 800, WASHINGTON, DC, 20006-1021, US

(21) Appl. No.: 12/073,521

(22) Filed: Mar. 6, 2008

Related U.S. Application Data
(62) Division of application No. 10/985,941, filed on Nov. 12, 2004.

(30) Foreign Application Priority Data
Nov. 14, 2003 (JP) 2003-385452

(51) Int. Cl. G03F 7/004

(52) U.S. Cl. 430/270.1

(57) ABSTRACT

Provided are a resist composition for separator formation which can be applied for forming separators in the form including a forward taper shape and a reverse taper shape and can be widely used for production of various organic EL displays, and a separator and an EL display device obtained from this resist composition. A composition containing an alkali-soluble resin, an acid generator, a cross-linking agent and a separator pattern shape controlling agent is used as the resist composition for separator formation of an EL display device and the like. The separator pattern shape controlling agent is preferably constituted of a forward taper controlling agent and a reverse taper controlling agent, and these controlling agents can be composed of an amine and an organic acid.

### CROSS-REFERENCE TO RELATED APPLICATIONS

This application claims the benefit of priority of Japanese Patent Application No. 2003-385452 filed on Nov. 14, 2003, and the disclosure of which is incorporated herein by its entirety.

### FIELD OF ART

The present invention relates to, for example, a resist composition for forming a separator of an EL display device, a separator of an EL display device, and an EL display device. More specifically, the present invention relates to a resist composition which can form a separator of an EL display device and the like, having a variety of shapes whose cross-section have arbitrary inclination angles including a forward taper shape and a reverse taper shape, a separator formed from this resist composition, and an EL display device having this separator.

### DESCRIPTION OF THE RELATED ART

As well known, an EL display device may be formed, for example, as described below.

That is, a transparent electrode layer such as ITO is first formed by sputtering on a glass substrate. On this transparent electrode layer, a positive photoresist is applied and pre-baked. The resist is exposed via a mask, and then developed to form a pattern. The ITO film is etched by an etchant using the patterned resist film as a mask, to form a patterned transparent electrode composed of ITO. After the resist film remaining on this patterned transparent electrode layer is removed, a resist for separator formation is applied to the glass substrate carrying the patterned transparent electrode formed thereon. This applied film is dried, and then patterning exposure and subsequent development is conducted thereon to form a separator. Thereafter, a hole transportation layer, an organic EL medium layer, and a cathode layer are sequentially laminated on the transparent electrode layer utilizing the separator. As the hole transportation layer, for example, phthalocyanine-based materials, or aromatic amines are used. As the organic EL medium, materials obtained by doping its base material with quinacridone or coumarin are used. Further, as the cathode material, for example, Mg—Al, Al—Li, Al—Li₂O, and Al—LiF are used. Next, a stainless can member having a hollow structure and the substrate are sealed with a sealing agent, followed by fabricating into a module to obtain an organic EL display device.

The shape of the separator has to be changed depending on the molecular weight of an organic EL material forming an organic EL layer such as a hole transportation layer and organic EL medium layer that are to be laminated utilizing this separator.

There have been developed a variety of organic EL materials from those having considerably low molecular weight to those having high molecular weight. From the standpoint of film formation, they are classified into lower molecular weight materials having a molecular weight of 1000 or less and higher molecular weight materials having a molecular weight of 10000 or more. When a material having a molecular weight of 1000 or less is prepared in a form of a solution, viscosity thereof is too low and it is difficult to form an applied film by an application method. Therefore, the film of such a material has to be made by a vapor deposition method. On the other hand, when a polymer material having a molecular weight of 10000 or more is prepared in a form of a solution, viscosity thereof is too high to make a film by the vapor deposition method. Thus, the film of such a material has to be made by the application method.

When an EL layer is formed using a lower molecular weight EL material, it is preferable, from the standpoint of dimensional accuracy of film formation, to accumulate a material vertically on a transparent electrode 2 from the upper direction of the transparent electrode 2 on a substrate 1 as shown in FIG. 1. Therefore, it is important to form a separator 3 having a section in the form of a reverse taper (reverse trapezoid) by putting an edge. Regarding a resist composition suitable for forming such a separator having a reverse taper shape, there have been proposed several compositions (Patent Document 1: Japanese Patent Application Laid-open No. 2002-83687, and Patent Document 2: Japanese Patent Application Laid-open No. 2002-83688).

On the other hand, when an EL layer is formed using a higher molecular weight EL material, a solution is poured on a transparent electrode 2 on a substrate 1 as shown in FIGS. 2 and 3 using an application method such as a spin coating method, a printing method and an inkjet method. Therefore, it is important to form the separator having a section in the form of a forward taper (trapezoid) like a separator 4 in FIG. 2 or a section in the form of arch like a separator 5 in FIG. 3.

When resist compositions disclosed in the Patent Documents 1 and 2 are used, it is possible to form a separator having a section in the form of the reverse taper, and it is expected to control its inclination angle to a certain extent. However, it is impossible to significantly control its inclination angle to give a separator section in the form of a forward taper. That is, a resist composition for forming a separator suitable for a lower molecular weight EL material is unavailable as a resist composition for forming a separator suitable for a high molecular weight EL material even if the composition ratio is extremely controlled.

This means that a resist composition for forming a separator suitable for a high molecular weight EL material is unavailable as a resist composition for forming a separator suitable for a lower molecular weight EL material even if the composition ratio is extremely controlled. If separators having any inclination angles from the reverse taper shape to the forward taper shape can be formed from a certain main composition merely by adjusting the containing ratio of the ingredients thereof, various managements including quality management of a resist composition, stock management, and improvement in quality are made easily, giving a significant merit for production. However, resist compositions for separator formation which can be applied for forming a variety of separators including those having the forward taper shape and the reverse taper shape and can be widely used for production of various organic EL displays are not hitherto known.

### SUMMARY OF THE INVENTION

The present invention was achieved in view of the above problems, and the object of the invention is to provide a resist composition for separator formation which can be applied to configuration of separators including those having the forward taper shape and those having the reverse taper shape and can be widely used for production of various organic EL displays, and to provide a separator obtained from this resist composition, and an EL display device having this separator.

For solving the above problems, “resist composition for separator formation” according to the present invention is a resist composition for separator formation suitable for forming a tapered separator in an EL display device and the like, wherein the composition contains an alkali-soluble resin, an acid generator, a cross-linking agent, and a separator pattern shape controlling agent.

The separator pattern shape controlling agent is preferably constituted of a forward taper controlling agent and a reverse taper controlling agent. As the reverse taper controlling agent, an amine is suitable, and as the forward taper controlling agent, an organic acid is suitable. The forward taper controlling agent decreases the side surface inclination angle of a separator and the reverse taper controlling agent increases the side surface inclination angle of a separator.

With the resist composition of the present invention, the side surface inclination angle of the resulting separator can be controlled at any angles in the range of at least from 5° to 130° in terms of internal angle, by controlling the containing ratio of the forward taper controlling agent and the reverse taper controlling agent which are components of the composition.

The separator of the EL display device of the present invention is characterized in that it is formed from the aforementioned resist composition. Further, the EL display device of the present invention is characterized in that it has the aforementioned specific separator. The EL display device of the present invention may include an organic EL display device and an inorganic EL display device.

In the resist composition described above, the shape of the resulting pattern may become a more reverse taper shape by increasing the amount of amine added, and becomes a more forward taper shape by increasing the amount of organic acid added. The amount of the amine added may be smaller than the amount of an ultraviolet inhibitor and dye. In general, when an ultraviolet inhibitor and dye are used, the sensitivity of the resist composition decreases. However, the resist composition of the present invention is advantageous in that decrease in sensitivity is not caused. Further, the resist composition of the present invention gives little sublimated substance in post-bake, and does not cause much deforming and degassing at heating. Thus, the present resist composition is suitably used for producing an EL display device. The resist composition of the present invention may be easily formed into a film with an application apparatus such as a spin coater, a spinless coater, and a roll coater.

When the composition ratio of the resist composition of the present invention is controlled to form a separator having the reverse taper shape, the lower molecular weight EL material may be suitably used for vapor deposition on a transparent electrode on a substrate with high precision. When the composition ratio is controlled to form a separator having the forward taper shape, the higher molecular weight EL material may be suitably used for pouring the solution thereof on a transparent electrode on a substrate. With the higher molecular weight EL material, an inkjet method may be employed for pouring the solution of the material on a transparent electrode, for producing the EL display device. Since the separator has the forward taper shape, even if the solution is poured on the side surface of the separator, the solution flows automatically along the taper surface onto the transparent electrode, thereby forming a film of good quality on the transparent electrode. The side surface of the separator in this case is not limited to a flat inclined surface, but may be any surface provided that it is inclined toward the transparent electrode. That is, the inclined surface may be flat or curved.

The amount of amine added may preferably be from a trace amount very near 0 wt % to 1 wt %, and more preferably from 0.1 wt % to 1 wt %, based on the amount of the alkali-soluble resin (solid content). When the amount of amine used exceeds 1 wt %, the angle of the reverse taper of the separator may become too sharp to maintain the shape thereof.

The amines for use may include aliphatic, aromatic and heterocyclic primary, secondary, and tertiary amines.

Examples of the aliphatic amines may include lower aliphatic amines such as trimethylamine, diethylamine, triethylamine, di-n-propylamine, tri-n-propylamine, trisopropylamine, dibutylamine, tributylamine, tripentylamine, diethanolamine, triethanolamine, diisopropanolamine, and triisopropanolamine.

Examples of the aromatic amines may include benzylamine, aniline, N-methylaniline, N,N-dimethylaniline, o-methylaniline, m-methylaniline, p-methylaniline, N,N-diethylaniline, diphenylamine, and di-p-tolylamine.

Examples of the heterocyclic amines may include pyridine, o-methylpyridine, o-ethylpyridine, 2,3-dimethylpyridine, 4-ethyl-2-methylpyridine, and 3-ethyl-4-methylpyridine.

The amount of the organic acid added may preferably be from a trace amount very near 0 to 0.6 wt %, and more preferably from 0.06 to 0.6 wt %, based on the amount of the alkali-soluble resin (solid content).

Such organic acids may include organic carboxylic acid, organic phosphonic acid, and organic sulfonic acid. The organic carboxylic acid may include aliphatic monocarboxylic acids such as formic acid, acetic acid, propionic acid, butyric acid, lauric acid, palmitic acid, and stearic acid; unsaturated aliphatic monocarboxylic acids such as oleic acid and linoleic acid; aliphatic dicarboxylic acids such as oxalic acid, succinic acid, adipic acid, and maleic acid; oxycarboxylic acids such as lactic acid, gluconic acid, malic acid, tartaric acid, and citric acid; and aromatic carboxylic acids such as benzoic acid, mandelic acid, salicylic acid, and phthalic acid.

The amount of the cross-linking agent added may preferably be 1 to 30 wt %, and more preferably 5 to 20 wt %, based on the amount of the alkali-soluble resin (solid content).

As the cross-linking agent, any compounds may be used so long as they cause a cross-linking reaction by an acid. Preferable examples of the cross-linking agent may include alkoxyalkylated amino resins such as alkoxyalkylated melamine resins and alkoxyalkylated urea resins as well as melamine based, benzoguanamine based, and urea based compound. Specific examples of the alkoxyalkylated amino resins may include a methoxymethylated melamine resin, a butoxymethylated melamine resin, a methoxymethylated urea resin, an ethoxymethylated urea resin, a propoxymethylated urea resin, and butoxymethylated urea resin.

The alkali-soluble resin may include a phenol novolak resin, a cresol novolak resin, a polyacrylic acid, a polyvinyl alcohol, a copolymer of styrene with maleic anhydride, a polyhydroxystyrene and derivatives thereof. Polyhydroxystyrene and derivatives thereof may include a homopolymer of vinylphenol, copolymers of vinylphenol with acrylic acid derivatives, acrylonitrile, methacrylic acid derivatives, methacrylonitrile, copolymer including styrene, or styrene derivatives such as α-methylstyrene, p-methylstyrene, o-methylstyrene, p-methoxystyrene, and p-chlorostyrene, hydrogenated resins of a vinylphenol homopolymer, and hydrogenated resins of copolymers of vinylphenol with the acrylic acid derivative, methacrylic acid derivative, or styrene derivative.

Preferable alkali-soluble resins may include a novolak resin, hydroxystyrene resin, and a mixture of novolak resin/hydroxystyrene resin. While the ratio of the novolak resin/hydroxystyrene resin is not particularly restricted, it may preferably be from 0/100 to 70/30. When the ratio of the novolak resin is 70 or more, heat resistance of a resist composition may lower.

As the acid generator, triazine-based and oxime sulfonate-based generators may be used, and oxime sulfonate-based generators are preferable, although it is not particularly restricted. This resist composition will be present as a permanent film in an EL display device after formation of the EL display device (when it is used as a separator). Therefore, when corrosion of an Al electrode in an EL display device is considered, oxime sulfonate-based generators are preferable because of low tendency of unreacted acid generation. When the amount of the acid generator is less than 3 wt %, sensitivity may lower and film loss may increase.

Examples of the oxime sulfonate-based acid generator may include
α-(methylsulfonyloxyimino)phenylacetonitrile,
α-(methylsulfonyloxyimino)-4-methoxyphenylacetonitrile,
α-(trifluoromethylsulfonyloxyimino)-phenylacetonitrile,
α-(trifluoromethylsulfonyloxyimino)-4-methoxyphenylacetonitrile,
α-(ethylsulfonyloxyimino)-4-methoxyphenylacetonitrile,
α-(propylsulfonyloxyimino)-4-methoxyphenylacetonitrile, and
α-(methylsulfonyloxyimino)-4-bromophenylacetonitrile.

Examples of the triazine-based acid generator may include triazine compounds such as 2,4-bis(trichloromethyl)-6-[2-(2-furyl)ethenyl]-s-triazine,
2,4-bis(trichloromethyl)-6-[2-(5-methyl-2-furyl)ethenyl]-s-triazine,
2,4-bis(trichloromethyl)-6-[2-(5-ethyl-2-furyl)ethenyl]-s-triazine,
2,4-bis(trichloromethyl)-6-[2-(5-propyl-2-furyl)ethenyl]-s-triazine,
2,4-bis(trichloromethyl)-6-[2-(3,5--dimethoxyphenyl)ethenyl]-s-triazine,
2,4-bis(trichloromethyl)-6-[2-(3,5--diethoxyphenyl)ethenyl]-s-triazine,
2,4-bis(trichloromethyl)-6-[2-(3,5--dipropoxyphenyl)ethenyl]-s-triazine,
2,4-bis(trichloromethyl)-6-[2-(3-methoxy-5-ethoxyphenyl)ethenyl]-s-triazine,
2,4-bis(trichloromethyl)-6-[2-(3-methoxy-5-propoxyphenyl)ethenyl]-s-triazine,
2,4-bis(trichloromethyl)-6-[2-(3,4--methylenedioxyphenyl)ethenyl]-s-triazine,
2,4-bis(trichloromethyl)-6-(3,4--methylenedioxyphenyl)-s-triazine,
2,4-bis-trichloromethyl-6-(3-bromo-4methoxy)phenyl-s-triazine,
2,4-bis-trichloromethyl-6-(2-bromo-4methoxy)phenyl-s-triazine,
2,4-bis-trichloromethyl-6-(2-bromo-4methoxy)styrylphenyl-s-triazine, and
2,4-bis-trichloromethyl-6-(3-bromo-4methoxy)styrylphenyl-s-triazine.

The resist compositions for separator formation of the present invention is applicable to configuration of separators in a variety of forms including the forward taper shape and the reverse taper shape and may be widely used for producing various organic EL display devices. With this resist composition, various separators adapted to various EL materials may be efficiently formed, which thus makes it possible to produce various EL display devices.

Other objects, features, and advantages of the present invention will become apparent from the following detailed description of the invention with reference to the accompanying drawings.

### BRIEF DESCRIPTION OF THE DRAWINGS

FIG. 1 is an explanatory view of a shape of section necessary for a separator for forming an EL display device when an EL material of an EL display device has low molecular weight.

FIG. 2 is an explanatory view of a shape of section necessary for a separator for forming an EL display device when an EL material of an EL display device has high molecular weight.

FIG. 3 is an explanatory view of another shape of section necessary for a separator for forming an EL display device, when an EL material of an EL display device has high molecular weight.

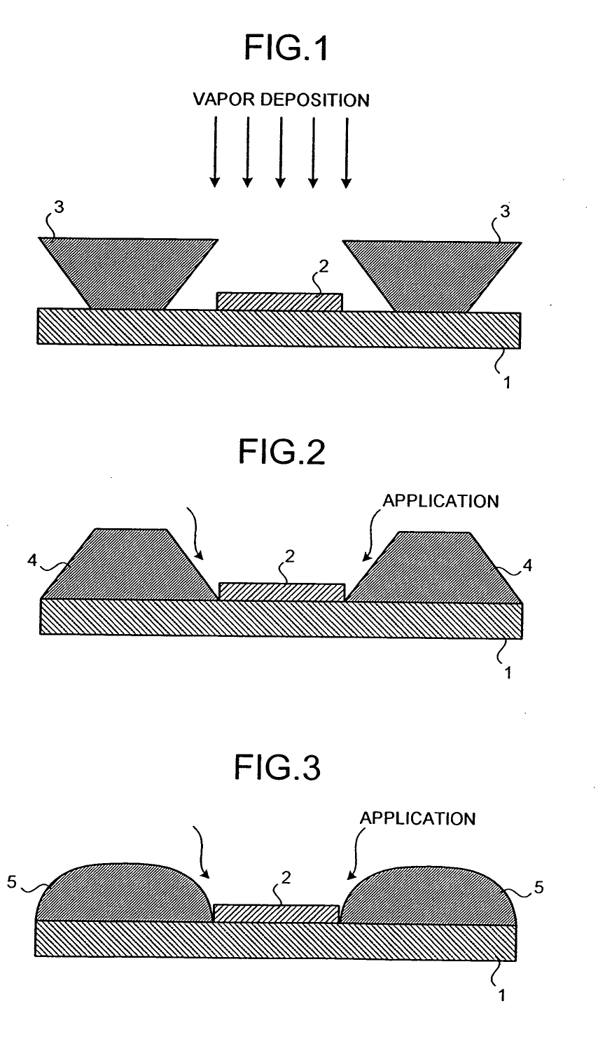

Numerals in the drawings indicate those listed below:

1: substrate

2: transparent electrode

3: separator having a cross-sectional shape in the form of a reverse taper

4: separator having a cross-sectional shape in the form of a forward taper

5: separator having a cross-sectional shape in the form of bottom spreading

### DETAILED DESCRIPTION OF THE INVENTION

Examples of the present invention will be explained hereinbelow. However, the following Examples are merely exemplification for suitably explaining the present invention. The present invention is not limited thereto.

### Examples of the Invention

Prior to descriptions of examples according to the present invention and comparative examples, components used in these examples will be listed below.

(A) novolak resin: manufactured by Gun Ei Chemical Industry Co., Ltd., trade name; GTR-G8/G9, m/p=100/0, Mw of G8=8000, Mw of G9=9000

(B) hydroxystyrene resin: manufactured by Nippon Soda Co., Ltd., trade name; VPS-2515, hydroxystyrene/styrene=85/15, Mw=2500

(C) PAG (acid generator): manufactured by Ciba Specialty Chemical, trade name: CGI-1397

((5-propylsulfonyloxyimino-5H-thiophen-2-ylydene)-(2-methylphenone)-acetonitrile)

(D) PAG (acid generator): manufactured by Junsei Chemical Co., Ltd., trade name: BU-84J

(α,α-bis(butylsulfonyloxyimino)-m-phenylenediacetonitrile; oxime sulfonate-based

(E) cross-linking agent: melamine manufactured by Sanwa Chemical Co., Ltd., trade name; Mw-100LM

(F) amine: manufactured by Tokyo Kasei Kogyo Co., Ltd., tri-n-pentylamine

(G) organic acid: manufactured by Junsei Chemical Co., Ltd., salicylic acid

(H) activating agent: manufactured by Dainippon Ink and Chemicals, Inc., F-Si-based activating agent, trade name; Megafack R-08

(I) dye: manufactured by Dainippon Pharmaceutical Co., Ltd., trade name; GARO KB-H

### Example 1

A solid component composed of 70 g of the novolak resin (A) and 30 g of the hydroxystyrene resin (B) was dissolved in 400 g of PGMEA (propylene glycol monomethyl ether acetate) to produce a resin liquid. To this resin liquid were added 7 g of the oxime sulfonate-based acid generator (C) and 15 g of the cross-linking agent (E). Further, 1 g of the amine (F), 0.06 g of the organic acid (G), and 0.1 g of the activating agent (H) were added, and the mixture was stirred. Thereafter, the mixture was filtered through a Millipore filter having a pore diameter of 0.05 μm to obtain an application liquid (negative resist composition).

### Example 2

A solid component composed of 100 g of the hydroxystyrene resin (B) was dissolved in 400 g of PGMEA, to produce a resin liquid. To this resin liquid were added 5 g of the oxime sulfonate-based acid generator (C) and 15 g of the cross-linking agent (E). Further, 0.75 g of the amine (F), 0.05 g of the organic acid (G), and 0.1 g of the activating agent (H) were added, and the mixture was stirred. Thereafter, the mixture was filtered through a Millipore filter having a pore diameter of 0.05 82 m to obtain an application liquid (negative resist composition).

### Example 3

A solid components composed of 30 g of the novolak resin (A) and 70 g of the hydroxystyrene resin (B) was dissolved in 400 g of PGMEA to produce a resin liquid. To this resin liquid were added 7 g of the oxime sulfonate-based acid generator (C), and 15 g of the cross-linking agent (E). Further, 0.1 g of the amine (F), 0.06 g of the organic acid (G), and 0.1 g of the activating agent (H) were added, and the mixture was stirred. Thereafter, the mixture was filtered through a Millipore filter having a pore diameter of 0.05 μm to obtain an application liquid (negative resist composition).

### Example 4

A solid component composed of 100 g of the hydroxystyrene resin (B) was dissolved in 400 g of PGMEA to produce a resin liquid. To this resin liquid were added 3 g of the acid generator (D) instead of the oxime sulfonate-based acid generator (C), and 10 g of the cross-linking agent (E). Further, 0.1 g of the amine (F), 0.3 g of the organic acid (G), and 0.1 g of the activating agent (H) were added, and the mixture was stirred. Thereafter, the mixture was filtered through a Millipore filter having a pore diameter of 0.05 μm to obtain an application liquid (negative resist composition).

### Comparative Example 1

A solid component composed of 100 g of the hydroxystyrene resin (B) was dissolved in 400 g of PGMEA to produce a resin liquid. To this resin liquid were added 7 g of the oxime sulfonate-based acid generator (C) and 15 g of the cross-linking agent (E). Further, 3 g of the dye (I) and 0.1 g of the activating agent (H) were added, instead of the amine (F) and the organic acid (G). The mixture was then stirred. Thereafter, the mixture was filtered through a Millipore filter having a pore diameter of 0.05 μm to obtain an application liquid (negative resist composition).

Each of the application liquids of Examples 1 to 4 and Comparative Example 1 was applied with a spin coater on a glass substrate on which ITO had been deposited, and dried at 110° C. for 90 seconds, to form an applied film having a thickness of 4 micron. These applied films were exposed to a wavelength of 365 nm (brilliance 35 mW/cm²) via a mask using an exposing machine (EXM-1066 E-1) manufactured by ORC, and subjected to P.E.B (Post Exposure Bake) at 110° C. for 90 seconds. Subsequently, development was carried out with a 2.38% tetramethyl ammonium hydroxide aqueous solution (manufactured by Tokyo Ohka Kogyo Co., Ltd., trade name; NMD-3), and the film was washed with pure water for 30 seconds, to form a pattern on the glass substrate. This pattern was heat-treated for 30 minutes in an oven of 200° C., to cure the pattern.

The shape of the cross-section of each pattern obtained as described above was observed, and the inclination angle (internal angle of the pattern) of a side surface with respect to the substrate was measured. The sensitivity and film thickness of each pattern were also measured. The results are shown in the following table (Table 1).

TABLE 1

| | Side surface inclination | Sensitivity | Film thickness |
|---|---|---|---|
| | angle | (mJ) | (μm) |
| Example 1 | 130° (reverse taper) | 40 | 3.8 |
| Example 2 | 120° (reverse taper) | 40 | 3.8 |
| Example 3 | 90° (rectangular section) | 30 | 3.8 |
| Example 4 | 50° (forward taper) | 20 | 3.8 |
| Comparative | 130° (reverse taper) | 60 | 3.6 |
| Example 1 | | | |

In Example 4, the amount of an organic acid added with respect to amine was greater than that in Examples 1, 2, and 3. Consequently, as seen from Table 1, the cross-section of the resulting pattern is of a reverse taper shape (rectangle) in Examples 1, 2, and 3, while in Example 4, it is of the forward taper shape. This difference is not attributed to difference in constituent components, but to difference in the ratio of the amine to the organic acid. In contrast, in Comparative Example 1 (prior art example), neither amine nor organic acid is contained as a constituent element, and even by changing the ratio of components, the shape of a pattern cannot be significantly changed unlike the composition according to the present invention.

In Comparative Example 1, sensitivity lowered because of addition of a dye. Further, a sublimated substance was generated in post bake, and heat resistance also lowered.

### Example 5

A solid component composed of 30 g of the novolak resin (A) and 70 g of the hydroxystyrene resin (B) was dissolved in 400 g of PGMEA to produce a resin liquid. To this resin liquid were added 7 g of the oxime sulfonate-based acid generator (C) and 15 g of the cross-linking agent (E). Further, 1 g of the amine (F) and 0.1 g of the activating agent (H) were added, and the mixture was stirred. Thereafter, the mixture was filtered through a Millipore filter having a pore diameter of 0.05 μm to obtain an application liquid (negative resist composition).

### Example 6

A solid component composed of 50 g of PHC LC 80-15 (trade name: hydroxystyrene:styrene=85:15, Mw=8000, manufactured by Toho Chemical Industry Co., Ltd.) and 50 g of PHC LC 80-05 (trade name: hydroxystyrene:styrene=95:5, Mw=8000, manufactured by Toho Chemical Industry Co., Ltd.), as a hydroxystyrene resin, was dissolved in 400 g of PGMEA to produce a resin liquid. To this resin liquid were added 3 g of the oxime sulfonate-based acid generator (D) and 10 g of the cross-linking agent (E). Further, 0.06 g of the organic acid (G) and 0.1 g of the activating agent (H) were added, and the mixture was stirred. Thereafter, the mixture was filtered through a Millipore filter having a pore diameter of 0.05 μm to obtain an application liquid (negative resist composition).

### Example 7

A solid component composed of 30 g of the novolak resin (A) and 70 g of the hydroxystyrene resin (B) was dissolved in 400 g of PGMEA to produce a resin liquid. To this resin liquid were added 7 g of the oxime sulfonate-based acid generator (C) and 15 g of the cross-linking agent (E). Further, 1 g of tridecylamine as an amine, 0.06 g of the organic acid (G), and 0.1 g of the activating agent (H) were added, and the mixture was stirred. Thereafter, the mixture was filtered through a Millipore filter having a pore diameter of 0.05 μm to obtain an application liquid (negative resist composition).

### Example 8

A solid component composed of 50 g of LC 81015 (hydroxystyrene:styrene=85:15, manufactured by Toho Chemical Industry Co., Ltd.) and 50 g of LC 8005 (hydroxystyrene:styrene=85:15, manufactured by Nippon Soda Co., Ltd.), as a hydroxystyrene resin was dissolved in 400 g of PGMEA to produce a resin liquid. To this resin liquid were added 3 g of the oxime sulfonate-based acid generator (D) and 10 g of the cross-linking agent (E). Further, 0.1 g of the amine (F) and, 0.3 g of succinic acid instead of the organic acid (E), were added, and the mixture was stirred. Thereafter, the mixture was filtered through a Millipore filter having a pore diameter of 0.05 μm to obtain application liquid (negative resist composition).

### Example 9

A solid component composed of 70 g of the novolak resin (A) and 30 g of the hydroxystyrene resin (B) was dissolved in 400 g of PGMEA to produce a resin liquid. To this resin liquid were added 3 g of p-methoxystyryl-s-triazine as a triazine-based acid generator, and 15 g of the cross-linking agent (E). Further, 1 g of the amine (F), 0.06 g of the organic acid (G), and 0.1 g of the activating agent (H) were added, and the mixture was stirred. Thereafter the mixture was filtered through a Millipore filter having a pore diameter of 0.05 μm to obtain an application liquid (negative resist composition).

### Comparative Example 2

An application liquid (negative resist composition) was obtained in the same manner as in Comparative Example 1 except that 100 g of the hydroxystyrene resin (B) was replaced by 70 g of the novolak resin (A) and 30 g of the hydroxystyrene resin (B).

Patterns were formed in the same manner as in Examples 1 to 4 and Comparative Example 1 from the application liquids in Examples 5 to 9 and Comparative Example 2, and the inclination angle was measured. The sensitivity and film thickness of each pattern were also measured. The results are shown in the following table (Table 2). The shape of the pattern in the examples is a reverse taper in Examples 5, 7, and 9 and Comparative Example 2, and is a forward taper in Examples 6 and 8.

TABLE 2

| | Side surface inclination | | Film thickness |
|---|---|---|---|
| | angle | Sensitivity (mJ) | (μm) |
| Example 5 | 130° (reverse taper) | 50 | 3.9 |
| Example 6 | 80° (forward taper) | 20 | 3.8 |
| Example 7 | 120° (reverse taper) | 50 | 3.8 |
| Example 8 | 50° (forward taper) | 20 | 3.8 |
| Example 9 | 130° (reverse taper) | 40 | 3.7 |
| Comparative | 105° (reverse taper) | 60 | 3.6 |
| Example 2 | | | |

In Example 5, the shape was a reverse taper when a separator pattern shape controlling agent was solely composed of an amine. In Example 6, the shape was a forward taper when a separator pattern shape controlling agent was solely composed of an organic acid. From these findings, it can be seen that addition of amine causes a reverse taper and addition of an organic acid causes a forward taper.

In Comparative Example 2, sensitivity lowered since a dye was used like in Comparative Example 1. Further, a sublimated substance was generated in post bake, and heat resistance also lowered.

### INDUSTRIAL APPLICABILITY

As described above, the negative resist compositions of the present invention can be applied for forming separators in the form including the forward taper shape and the reverse taper shape, only by changing mutual ratio of components. Thus, it can be widely used for production of various organic EL displays, and various separators corresponding to various EL materials can be efficiently formed by this resist composition, and various EL display devices can be produced efficiently.

Although the present invention has been described with reference to the preferred examples, it should be understood that various modifications and variations can be easily made by those skilled in the art without departing from the spirit of the invention. Accordingly, the foregoing disclosure should be interpreted as illustrative only and is not to be interpreted in a limiting sense. The present invention is limited only by the scope of the following claims along with their full scope of equivalents.

1-6. (canceled)

7. A method for adjusting a separator to be formed such that it is possible to control a side surface inclination angle of the separator at any angle in a range of 5 degrees to 130 degrees, in terms of an internal angle, using a separator-forming resist composition for forming a taper-shaped separator comprising an alkali-soluble resin, an acid-generator, a cross-linking agent, and at least one compound selected from an organic acid and an amine, by adjusting the ratio of the organic acid and the amine in a range of 0.06% to 0.6% by weight for the organic acid and 0.1% to 1% by weight for the amine.

8. The method according to claim 7, wherein the alkali-soluble resin is at least one resin selected from a novolac resin and a hydroxystyrene resin.

9. The method according to claim 8, wherein the weight ratio of novolak resin to hydroxystyrene resin is from 0:100 to 70:30.

10. The method according to claim 7, wherein the acid-generator is an oxime group containing acid-generator.

11. A separator of an EL display device formed by the method of claim 7.

12. An EL display device having the separator according to claim 11.
